(19) United States
(12) Patent Application Publication
(10) Pub. No.: US 2019/0096472 A1
(43) Pub. Date: Mar. 28, 2019

(54) MEMORY CHIP HAVING REDUCED BASELINE REFRESH RATE WITH ADDITIONAL REFRESHING FOR WEAK CELLS

(71) Applicant: Intel Corporation, Santa Clara, CA (US)

(72) Inventors: Uksong KANG, Hillsboro, OR (US); John B. HALBERT, Beaverton, OR (US)

(21) Appl. No.: 15/714,789

(22) Filed: Sep. 25, 2017

(51) Int. Cl. G11C 11/406

(52) U.S. Cl. CPC G11C 11/40615

(57) ABSTRACT

A method performed by a memory chip is described. The method includes specially requesting additional refreshes for weak storage cells of the memory chip that deplete their charge more rapidly than other storage cells of the memory chip. The additional refreshes are added to a distributed baseline refresh command sequence that is applied to the weak storage cells and the other storage cells. The distributed baseline refresh command sequence has a refresh rate that is determined from charge depletion characteristics of the other storage cells.

### FIELD OF INVENTION

The field of invention pertains generally to the computing sciences, and, more specifically, to a memory chip having a reduced baseline refresh rate with additional refreshing for weak cells.

### BACKGROUND

A pertinent issue in many computer systems is the system memory (also referred to as “main memory”). Here, as is understood in the art, a computing system operates by executing program code stored in system memory and reading/writing data that the program code operates on from/to system memory. As such, system memory is heavily utilized with many program code and data reads as well as many data writes over the course of the computing system's operation. Finding ways to improve system memory accessing performance is therefore a motivation of computing system engineers.

### FIGURES

A better understanding of the present invention can be obtained from the following detailed description in conjunction with the following drawings, in which:

FIG. 1 shows a memory array (prior art);

FIG. 2 shows a memory chip having a weak cell table;

FIG. 3 shows comparison of a traditional refreshing approach and an improved refreshing approach;

FIG. 4 shows a memory system capable of performing an improved refreshing approach;

FIG. 5 shows a method of performing an improved refreshing approach;

FIG. 6 shows a computing system.

### DETAILED DESCRIPTION

Present day memory implementations typically include dynamic random access memory (DRAM) chips that are coupled to a memory controller through a memory channel (also referred to as a memory bus). The memory controller is responsible for sending appropriate commands to the DRAM memory chips for writing/reading data to/from the DRAM memory chips but also sending various other types of commands that keep the DRAM memory chips in proper working condition.

One of these commands is a refresh command. As is known in the art, a DRAM memory's storage cell is a small capacitance. The information stored by the cell is a function of the amount of charge stored by the capacitance (e.g. a first amount of charge corresponds to a “1” and a second amount of charge corresponds to a “0”). Unfortunately, the storage cells of a DRAM memory deplete their charge over time which, in turn, requires them to be periodically “refreshed” with additional charge to retain their stored data.

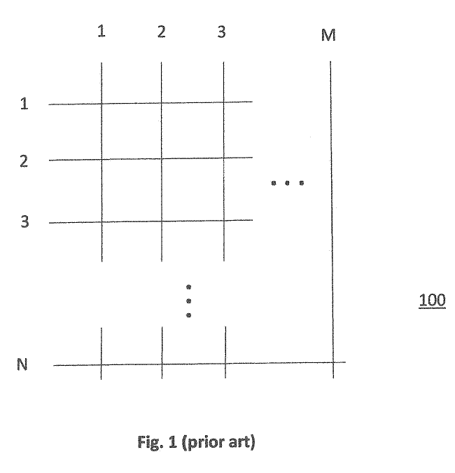

FIG. 1 shows a DRAM memory's storage cell array 101 which can be viewed as N rows and M columns. A number of storage cells (e.g., 8, 16, 32) are typically associated with each intersection of a row and column. According to a “distributed” refresh approach, a Refresh_Cycle_Interval is established for the DRAM memory's storage cells that defines how often each cell in the array will be refreshed. During runtime, the memory controller sends refresh commands to the rows of the DRAM memory's storage cell array in succession and then repeats the process such that each row receives a refresh command every Refresh_Cycle_Interval. The amount of time between consecutive refresh commands (e.g., sent to first and second neighboring rows) is referred to as the Refresh_Time. That is,

Refresh_Cycle_Interval=(Refresh_Time)/(#_of_Rows) Eqn. 1

A problem is that as DRAM storage cells shrink in size with each new manufacturing generation, they tend to more rapidly deplete their charge. The tendency of the cells to deplete their charge more rapidly increases the frequency at which refresh commands must be sent from the memory controller, which, in turn, diminishes the performance of the memory channel and/or memory chip because more time is devoted to refresh signals at the expense of read/write signals. Additionally, the power consumption of the memory system is increased because the higher refresh rate is akin to a constant, higher frequency background write process.

Interestingly, the needed refresh cycle interval for a significant number of the storage cells is much longer than the Refresh_Cycle_Interval that is actually used. That is, typically, most of the storage cells in the storage cell array 101 do not need to be refreshed at the rate at which they are refreshed (they could be refreshed at longer intervals and still properly retain their data).

Here, the established Refresh_Cycle_Interval is essentially driven by the far fewer “weakest” storage cells in the array 101. That is, a smaller percentage of manufactured cells require more frequent refreshing (they leak their charge more quickly). Because these weaker cells need more frequent refreshing, all of the storage cells in the memory array 101 are refreshed at the faster rate even though a large majority of the storage cells do not actually require it.

For example, if 64 ms were the nominal Refresh_Cycle_Interval configuration setting, a vast majority of storage cells in the memory array 101 could reliably retain their data if the Refresh_Cycle_Interval were increased to 128 ms. An improved approach, therefore, is to increase the baseline Refresh_Cycle_Interval (e.g., out to 128 ms) and then specially send more frequent refreshes to the relatively fewer weaker storage cells that actually need them.

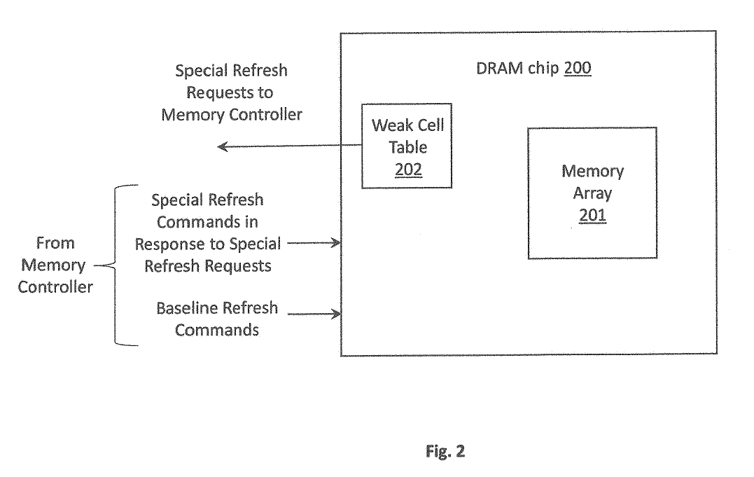

FIG. 2 therefore shows an improved DRAM memory chip 200 that maintains internal information that identifies which ones of its storage cells require more frequent refreshing (a weak cell table 202). When respective next refresh times for weaker cells are imminent, the DRAM memory chip 200 sends corresponding special requests to the memory controller to issue special refresh commands. Here, in various embodiments, the special refresh command is “special” because its generation is triggered by the needs of one or more weaker cells (e.g., is sent in response to a special refresh request) and not because of any special refresh command formatting (a special refresh command is sent by the memory controller using the nominal/standard refresh command (REF) formatting and/or timing on the memory channel).

The memory controller responds with the sending of the special refresh commands which the DRAM memory chip 200 applies to the refreshing of the weaker cells within the memory cell array 201. Here, the refresh commands for the weaker cells are deemed special because a slower baseline Refresh_Cycle_Interval is established for the DRAM memory chip that the memory controller issues periodic refresh commands according to. In some embodiments the baseline refresh requests are issued by the memory controller without requests being sent for them by the DRAM memory chip beforehand, while, in other embodiments, the baseline refresh requests are issued by the memory controller in response to refresh requests that were sent by the DRAM memory chip beforehand. For ease of discussion the following description will refer mainly to embodiments in which the memory chip issues baseline requests to the memory controller.

As alluded to above, in various embodiments, the nominal refresh commands that are sent by the memory controller at the slower baseline Refresh_Cycle_Interval are the only refresh commands used to generate refreshes for the large majority of storage cells that can reliably retain their data at the slower baseline rate.

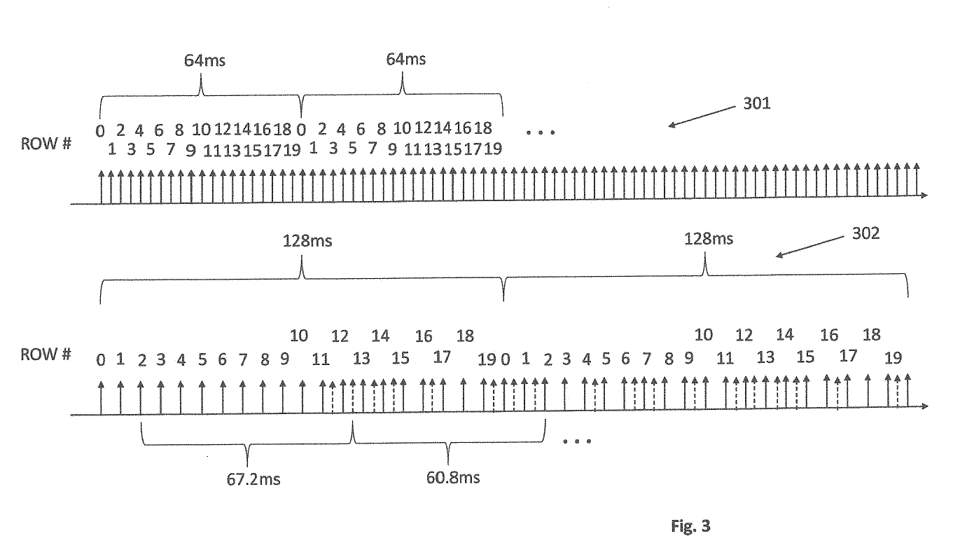

FIG. 3 shows an example of the refresh command timing for the improved approach as compared to the traditional approach having a higher baseline rate. Here, refresh command sequence 301 corresponds to the traditional approach in which refresh commands are sent at a higher baseline rate of every 64 ms to each row. In this particular example, for the ease of illustration, the memory array is assumed to include only twenty rows. As such, twenty rows are each separately refreshed at a baseline rate of 64 ms. The time between consecutive refreshes, from Eqn. 1, is 64 ms/20=3.2 ms.

By contrast, with respect to the improved approach depicted in sequence 302, a baseline rate of 128 ms is utilized which sets the time between refreshes for the baseline refresh pattern to 128 ms/20=6.4 ms (baseline refreshes are depicted as solid refresh arrows). Thus, the baseline refresh frequency is halved in the improved approach of sequence 302 which substantially frees up the memory channel and/or memory chip bandwidth to service read/write requests and/or lessens the power consumed by the memory controller and DRAM memory refreshing the DRAM's memory cells.

The improved sequence 302 also shows “special” refresh commands (depicted as dashed arrows) that are specially sent for those (relatively fewer) DRAM storage cells that may lose their data if they are refreshed at the 128 ms baseline rate. Here, some of the weaker cells need to be refreshed approximately every 64 ms whereas other significantly weaker (weakest) cells need to be refreshed approximately every 32 ms. As depicted in sequence 302, rows 0, 1, 5, 7, 8, 9, 11, 13, 15, 18 and 19 are understood to not include any weaker cells. As such, as observed in sequence 302, each of these rows are refreshed every 128 ms.

By contrast, rows 2, 3, 4, 10, 16 and 17 are understood to contain weaker cells that need refreshing approximately every 64 ms but do not include any of the weakest cells that require refreshing every 32 ms. As such, rows 2, 3, 4, 10, 16 and 17 receive a baseline refresh every 128 ms and a secondary refresh on average every 64 ms after each baseline refresh. For ease of discussion, FIG. 3 only contains added features for understanding the additional refreshes for row 0. Here, a first additional refresh for row 0 is observed halfway between the baseline refreshes for rows 12 and 13 (which occurs 64+3.2=67.2 ms after the first baseline refresh for row 0).

The next refresh for row 0 occurs 64−3.2=60.8 ms after the first additional refresh for row 0 (between the baseline refresh for rows 12 and 13) and corresponds to the second baseline refresh for row 0. The next refresh for row 0 corresponds to a special/additional refresh that is occurs halfway between the baseline refreshes for rows 12 and 13 in the second 128 ms baseline refresh cycle. The additional/special refreshes for rows 3, 4, 10, 16 and 17 are also depicted in sequence 302 and are positioned according to the scheme described just above for row 0.

Here, depending on implementation, the special refreshes may be directed to only the weaker cells on rows 2, 3, 4, 10, 16 and 17, or, may be directed to all cells on the row. The former approach will demonstrate greater power savings but involves a slightly more complex electrical design (selectively refreshing only the weaker cells that are coupled to a same row). The later approach does not involve any design complexities but will not be as power efficient.

Lastly, rows 6 and 14 are understood to include weakest cells that require special refreshing every 32 ms on average (but no weaker cells that require refreshing every 64 ms). Here, a first refresh for row 6 corresponds to the baseline refresh for row 6 that is scheduled in the first 128 ms baseline refresh cycle. A next refresh for at least the weakest cells on row 6 is a first special refresh that occurs halfway between the baseline refreshes for rows 11 and 12 in the first 128 ms baseline refresh cycle (32+3.2=35.2 ms) after the initial baseline refresh for row 6).

A next (third) refresh for at least the weakest cells of row 6 is a second special refresh that occurs halfway between the baseline refresh for rows 16 and 17 in the first 128 ms baseline refresh cycle (32 ms after the first special refresh). A next (fourth) refresh for at least the weakest cells of row 6 is a third special refresh that occurs halfway between the baseline refreshes for rows 1 and 2 in the second, 128 ms baseline cycle (32 ms after the second special refresh). A next (fifth) refresh for at least the weakest cells of row 6 is the nominal baseline refresh for row 6 during the second 128 ms baseline cycle (32−3.2=28.5 ms after the fourth refresh). Refreshes for row 14 follow a similar pattern.

Notably, from the above examples, average refreshes of 64 ms are achieved for weaker cells and average refreshes of 32 ms are achieved for weakest cells which are deemed sufficient to maintain data reliability of these cells.

For ease of explanation the above example does not include cells from different rows whose special refreshing schedule presents a situation where two different rows would be scheduled to concurrently receive a refresh. The situation may be avoided, e.g., by adopting only one special refresh rate granularity (e.g., only adopting a 64 ms special refresh granularity) and replacing weakest cells that would require a finer refresh granularity with redundant replacement cells in the memory array. Alternatively, the electrical design of the memory array could be enhanced to provide for selective refreshment of cells on different rows during a same refresh sequence.

Also for ease of explanation, the memory is not understood to include any rows that contain both weaker and weakest cells. Such rows, if they existed, would receive a special refresh every 32 ms increment after a baseline refresh. Again, refreshes could be selectively applied only to the cells that need them or could be applied to all the cells of the row.

Comparing the combined refresh pattern of the improved sequence 302 that includes both baseline and special refreshes, note that there are only 32 refresh commands per cycle (the second 128 ms cycle of sequence 302 shows the complete refresh pattern). By contrast, in the traditional sequence 301 there are 40 refresh commands per 128 ms (two 64 ms cycles).

Thus, because large numbers of cells only require a 128 ms refresh, there are less total refreshes per unit time with the improved approach 302 than with the traditional approach 301, which, in turn, corresponds to improved memory system performance and/or reduced power consumption with the improved approach 302. Moreover, if only weaker/weakest cells are selectively refreshed during a special refresh rather than refreshing all cells on a row having a weaker/weakest cell, the overall power savings are even more pronounced, because, as explained at length above, relatively few cells require the extra/special refreshes.

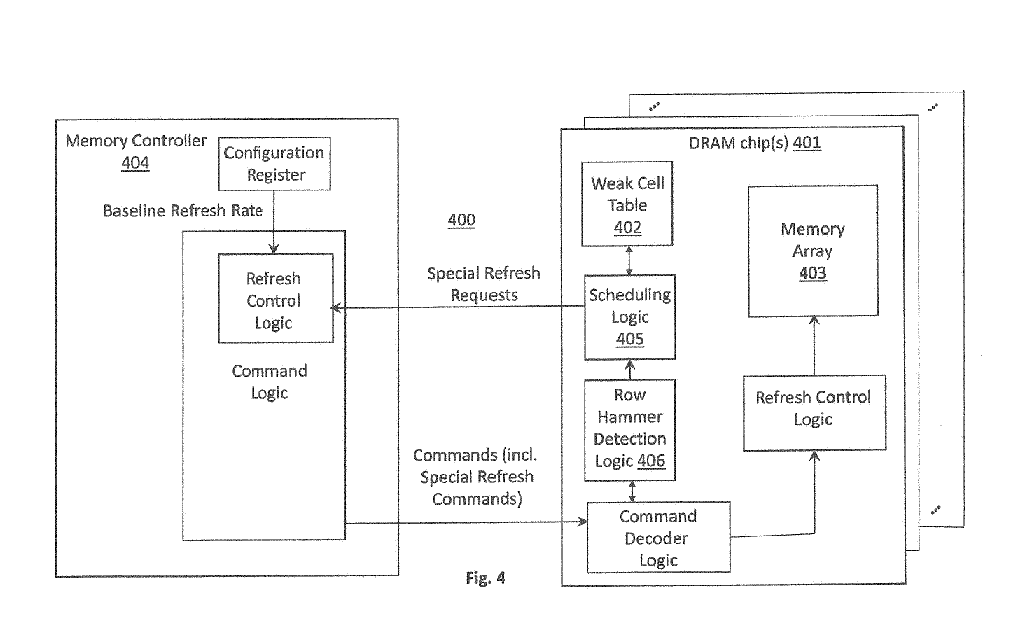

FIG. 4 shows a memory system design 400 that includes one or more DRAM memory chips 401 that each include embedded memory 402 to keep identifiers of storage cells that require additional, special refreshes and, in various embodiments, information that identifies how many additional, special refreshes are needed per cycle (or from which such information can be determined (e.g., 32 ms, 64 ms)).

Testing is performed on the cells of the memory array 403 to determine which cells are more prone to charge leakage and will therefore need additional refreshing. The testing may be performed by writing data to the DRAM memory's storage cells and reading the data back while refreshing the cells at slower and slower rates. Eventually the written data will become unreliable, at least for some cells (typically), and an understanding of how frequently each cell needs to be refreshed in order to reliably keep its data will be learned. The results of the learning are then entered in embedded memory 402.

Embedded memory 402 may be a read only memory (ROM) in the case where the testing is performed by the DRAM manufacturer (i.e., the memory is programmed once by the manufacturer during manufacturing of the DRAM)). Alternatively, embedded memory 402 may be an embedded SRAM or DRAM memory that is loaded during a power on or reset of the memory chip 401. In the case of the later, the learning procedure that determines which cells need extra refreshes (and how many refreshes) is performed, e.g., each time the DRAM chip is powered on or reset. Testing circuitry that performs the writing and reading back of the test data and/or performs the analysis on the test results may be embedded on the DRAM memory 401 (which is not shown in FIG. 4 for ease of illustration), or may be integrated in the memory controller 404, or may be integrated on both the DRAM memory 401 and the memory controller 404.

Here, once populated with the identifiers of the weak cells and the amount of refreshing they each need, embedded memory 402 may be referred to as a weak cell table 402. Weak cells may be identified in the table by their memory address (e.g. a combination of the memory array's row address and column address). Importantly, in various embodiments, the weak cell table 402 is kept on the DRAM memory 401 and not on the memory controller 404.

Here, the DRAM memory 401 includes scheduling logic circuitry 405 that scans the weak cell table 402 and recognizes when a cell needs refreshing. The scheduling logic 405 then sends a special refresh request to the memory controller 404 when an additional refresh for the cell is imminently needed (e.g., a set number of memory channel clock cycles prior to the needed special refresh). By keeping the special refresh intelligence 405 locally within the DRAM memory 401, the memory controller 404 does not need not to keep track of which cells are weak and how often or when they need to be refreshed.

During normal bring-up (e.g., each power on sequence/boot-up of the memory system), the baseline refresh rate is communicated, e.g., from BIOS firmware to the memory controller 404 (e.g., by being entered into a configuration register of the memory controller 404). Alternatively, the baseline refresh rate may be embedded in ROM circuitry of the memory 401 and communicated to the memory controller 404.

After bring-up, during normal runtime, refresh control logic circuitry 406 of the memory controller 404 issues a standard distributed baseline refresh sequence (e.g., as discussed above with respect to FIG. 3). Here, the refresh control logic circuitry of the memory controller may include timer logic circuitry to determine the correct timings of the sending of the refresh signals. However, as discussed at length above, the standard distributed baseline refresh rate runs at a slower rate because the weaker cells that need higher refresh rates will be specially refreshed. While the memory controller 404 is issuing the standard baseline refresh command sequence, the scheduling logic 405 within the DRAM memory 401 monitors the progress of the sequence and issues a special request to the memory controller 404 when a next scheduled special refresh command is coming due. In response, the memory controller 404 issues the specially requested refresh command.

In response to its receipt of the refresh command, the DRAM memory chip 401 provides extra refreshing to the row(s) or weak cell(s) on the row(s) that need the extra refreshing. Over time, as discussed above with respect to exemplary sequence 302 of FIG. 3, the requests made by the scheduling logic 405 will impose a repeating pattern of additional refreshes “on top of” the standard baseline memory refreshes that are issued by the memory controller 404.

In an embodiment, the special refresh requests are sent over a special dedicated I/O wire of the memory channel that couples the memory controller 404 and memory chips(s) 401. That is, in an embodiment, the DRAM memory chip 401 has a special output to issue special refresh requests to the memory controller 404 and the memory channel that couples the memory controller 404 and memory chip 401 has special signal wire(s) reserved for transportation of the special refresh requests to the memory controller 404. The memory controller 404, having an interface that is compatible with the memory channel, will also have a special input to receive the special refresh requests. In other embodiments, some other request path from the DRAM to the memory controller may exist (e.g., a general or dedicated communication channel from the DRAM to the memory controller is provided for in the industry standard specification that the memory channel that couples the memory controller and DRAM is designed according to) and the special refresh requests are sent along that path (e.g., multiplexed along with other kinds of communications/requests from the DRAM to the memory controller).

Additionally, because the DRAM memory 401 has the ability to request special refresh requests, the DRAM may include row hammer logic 406 that also utilizes the special refresh request output channel to the memory controller 404. Here, as is understood in the art, a row that is nearby (e.g., next to) a heavily accessed row (and/or is between two heavily accessed rows) can have its data corrupted because of the excessive access activity of its neighbor rows.

Traditionally, memory controllers have been designed with row hammer detection logic circuitry 406 that studies the addresses being applied to the memory chips and can determine if a particular row in a memory chip may be in danger of suffering row hammer corruption. If so, the memory controller issues a special refresh request to the memory chip(s) with an associated address that corresponds to the row that is in danger. The receiving memory chip(s) decode the address and apply the refresh to the row in danger to effectively remove the danger.

However, because the DRAM memory chip 401 includes scheduling logic circuitry 405 that can issue a special refresh request to the memory controller 404, the DRAM memory chip 401 may also be integrated with row hammer detection logic 406, e.g., instead of the memory controller 404. That is, the row hammer detection logic 406 on the DRAM memory chip 401 may study the addresses being applied to the memory chip 401, detect if a row is in danger of suffering from row hammer corruption, and, if so, issue a special refresh request over the special channel to the memory controller 404. In response, the memory controller 404 will issue the requested refresh command and the DRAM memory chip 401 will apply the refresh command to the row that is in danger of suffering a row hammer corruption.

Here, command decoder logic of the memory chip 401 may be coupled to a command/address (CA) bus of a memory channel such as an industry standard memory channel whose specifications are defined by a Joint Electron Device Engineering Council (JEDEC) industry standard publication. The command decoder logic decodes special refresh commands for weaker cells and row hammer refresh commands (each of which may be specified with different command words on the CA bus). Again, in various embodiments, the formatting/timing of any “special” refresh commands may be no different than standard refresh commands (REF).

The special refresh commands issued by the memory controller for the purpose of refreshing weaker cells may also include some identification of the weaker cells (which may have been appended to the memory chip's earlier request) so the memory chip 401 can synchronize the progress of the memory controller's responses to the memory chip's requests. Alternatively, no such information may be provided in either special refreshes for weaker cells or for row hammer refreshes that are requested by the memory chip because the memory chip requested the refreshes and knows to which cells/rows they are to be applied.

In various embodiments, the weak cell table 402 may be implemented with a bloom filter or other data tabulating approach that sacrifices some accuracy (increased false positives) for reduced memory footprint consumption of the weak cell table 402.

In another embodiment, some limit is placed on the number of special refreshes that are allowed to be scheduled to ensure that memory system performance enhancement and/or memory power consumption reduction is actually achieved. For example, if a traditional (e.g., 64 ms) distributed baseline refresh sequence would yield 8K refresh requests per 64 ms cycle, an improved approach that reduces the baseline refresh request rate by half (8K refresh requests per 128 ms cycle) would yield 4K baseline requests per 64 ms. If the process of identifying weak cells and scheduling special refreshing requests for them yielded 4K additional (special) requests, the special request approach could be dropped in favor of the traditional approach.

In further embodiments, a guaranteed improvement in performance/power if the new approach is used could be effected if some percentage of the “freed up” requests are not allowed to be used. For example, referring to the example discussed just above in which there is a difference of 4K between the number of baseline refreshes for the traditional approach and the special refresh approach, if more than 2K of special additional refreshes are needed for the special refresh approach, then the special refresh approach is not adopted (the traditional approach is used instead). So doing ensures a guaranteed performance/power improvement of at least 25% (with respect to refreshing) if the special refresh approach is adopted. The logic circuitry for determining which mode to use may be integrated in the memory circuit 401, the memory controller 404, configuration software of a larger system or some combination of these.

In still yet other embodiments, the memory chip maintains all logic circuitry and intelligence to control the special refreshes. That is, special refreshes do not require receipt of refresh commands from the memory controller beforehand. Here, for instance, the memory chip or the dual in line memory module (DIMM) that the memory chip is mounted on has sufficient buffer space to queue incoming requests (including write requests with corresponding data) should the target for the incoming request need special refreshing approximately the same time the incoming request is received. The memory chip may also maintain all logic circuitry and intelligence to control the baseline refreshes.

It is pertinent to recognize that the baseline rate of 128 ms emphasized above was only exemplary and that other baseline rates are possible including baseline rates that are greater than 128 ms (e.g., 256 ms, 512 ms, 1024 mc, any baseline rate within a range of 256 ms to 1024 ms, etc.)

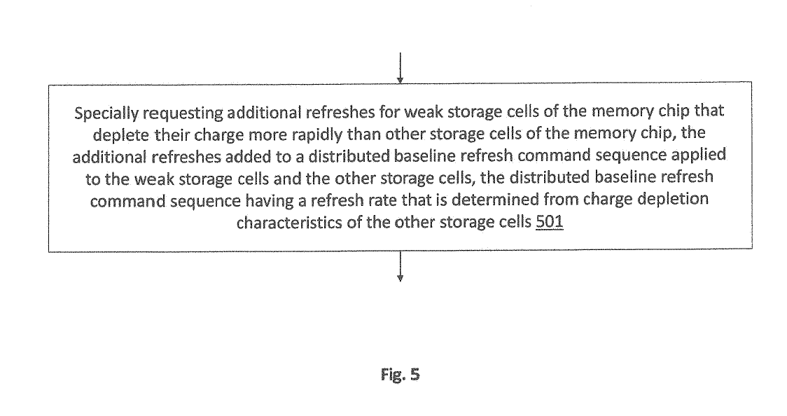

FIG. 5 shows a method performed by a memory chip. The method includes specially requesting additional refreshes for weak storage cells of the memory chip that deplete their charge more rapidly than other storage cells of the memory chip, the additional refreshes are added to a distributed baseline refresh command sequence that is applied to the weak storage cells and the other storage cells, the distributed baseline refresh command sequence has a refresh rate that is determined from charge depletion characteristics of the other storage cells.

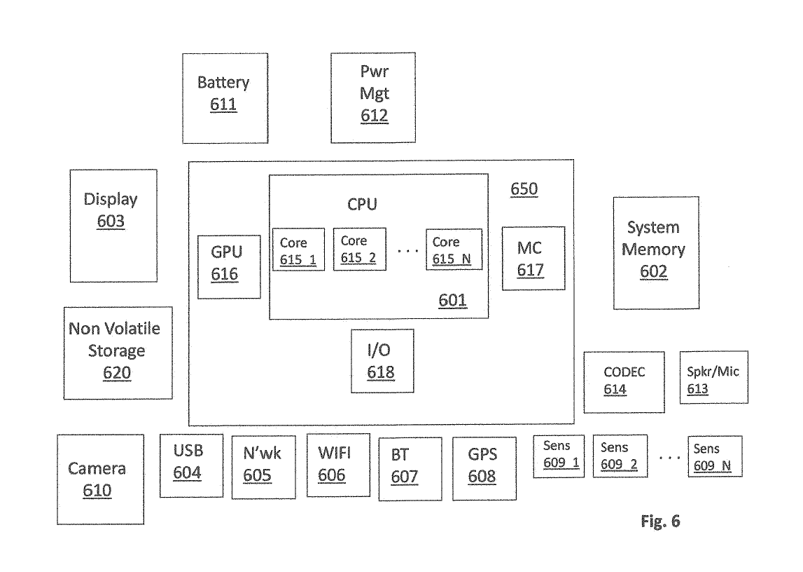

FIG. 6 provides an exemplary depiction of a computing system 600 (e.g., a smartphone, a tablet computer, a laptop computer, a desktop computer, a server computer, etc.). As observed in FIG. 6, the basic computing system 600 may include a central processing unit 601 (which may include, e.g., a plurality of general purpose processing cores 615_1 through 615_X) and a main memory controller 617 disposed on a multi-core processor or applications processor, system memory 602, a display 603 (e.g., touchscreen, flat-panel), a local wired point-to-point link (e.g., USB) interface 604, various network I/O functions 605 (such as an Ethernet interface and/or cellular modem subsystem), a wireless local area network (e.g., WiFi) interface 606, a wireless point-to-point link (e.g., Bluetooth) interface 607 and a Global Positioning System interface 608, various sensors 609_1 through 609_Y, one or more cameras 610, a battery 611, a power management control unit 612, a speaker and microphone 613 and an audio coder/decoder 614.

An applications processor or multi-core processor 650 may include one or more general purpose processing cores 615 within its CPU 601, one or more graphical processing units 616, a memory management function 617 (e.g., a memory controller) and an I/O control function 618. The general purpose processing cores 615 typically execute the operating system and application software of the computing system. The graphics processing unit 616 typically executes graphics intensive functions to, e.g., generate graphics information that is presented on the display 603. The memory control function 617 interfaces with the system memory 602 to write/read data to/from system memory 602. The power management control unit 612 generally controls the power consumption of the system 600.

Each of the touchscreen display 603, the communication interfaces 604-1107, the GPS interface 608, the sensors 609, the camera(s) 610, and the speaker/microphone codec 613, 614 all can be viewed as various forms of I/O (input and/or output) relative to the overall computing system including, where appropriate, an integrated peripheral device as well (e.g., the one or more cameras 610). Depending on implementation, various ones of these I/O components may be integrated on the applications processor/multi-core processor 650 or may be located off the die or outside the package of the applications processor/multi-core processor 650.

The computing system may also include a system memory (also referred to as main memory) implemented with a connector technology that provides for more than one DIMM per motherboard DIMM connector as described at length above.

Application software, operating system software, device driver software and/or firmware executing on a general purpose CPU core (or other functional block having an instruction execution pipeline to execute program code) of an applications processor or other processor may perform any of the functions described above.

Embodiments of the invention may include various processes as set forth above. The processes may be embodied in machine-executable instructions. The instructions can be used to cause a general-purpose or special-purpose processor to perform certain processes. Alternatively, these processes may be performed by specific hardware components that contain hardwired logic for performing the processes, or by any combination of programmed computer components and custom hardware components.

Elements of the present invention may also be provided as a machine-readable medium for storing the machine-executable instructions. The machine-readable medium may include, but is not limited to, floppy diskettes, optical disks, CD-ROMs, and magneto-optical disks, FLASH memory, ROMs, RAMs, EPROMs, EEPROMs, magnetic or optical cards, propagation media or other type of media/machine-readable medium suitable for storing electronic instructions. For example, the present invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. A memory chip, comprising:
an array of storage cells;
embedded memory circuitry to store information that identifies weak ones of the storage cells that deplete their charge more rapidly than other ones of the storage cells;
row hammer detection logic circuitry;
special refresh request logic circuitry coupled to the embedded memory circuitry and the row hammer detection logic circuitry, the special refresh request logic circuitry to send first special refresh requests to a memory controller on behalf of the weak ones of the storage cells in order to refresh the weak ones of the storage cells more frequently than the other ones of the storage cells, the special refresh request logic to also send second special refresh requests upon the row hammer detection logic detecting a row hammer condition; and,
command decode logic circuitry that is able to differentiate between first refresh commands that are to refresh the weak ones of the storage cells and second refresh commands that are to mitigate a row hammer hazard.

2. The memory chip of claim 1 wherein the memory chip comprises an output that is reserved for the special refresh requests.

3. The memory chip of claim 1 wherein the output is specified in a JEDEC memory channel standard.

4. (canceled)

5. The memory chip of claim 1 wherein the command decoding logic is to be coupled to CA signaling lines of a memory channel.

6. The memory chip of claim 5 wherein the memory channel's specifications are defined in a JEDEC industry standard.

7. (canceled)

8. (canceled)

9. A computing system, comprising:
a plurality of processing cores;
a system memory controller;
a system memory coupled to the system memory, the system memory comprising a memory chip, the memory chip comprising a), b), and c) below:
a) an array of storage cells;
b) embedded memory circuitry to store information that identifies weak ones of the storage cells that deplete their charge more rapidly than other ones of the storage cells;
c) row hammer detection logic circuitry;
d) special refresh request logic circuitry coupled to the embedded memory circuitry and the row hammer detection logic circuitry, the special refresh request logic circuitry to send first special refresh requests to a memory controller on behalf of the weak ones of the storage cells in order to refresh the weak ones of the storage cells more frequently than the other ones of the storage cells, the special refresh request logic to also send second special refresh requests to the system memory controller upon the row hammer detection logic detecting a row hammer condition; and,
e) command decode logic circuitry that is able to differentiate between first received refresh commands that are to refresh the weak ones of the storage cells and second refresh commands that are to mitigate a row hammer hazard.

10. The computing system of claim 9 wherein the memory chip comprises an output that is reserved for the special refresh requests.

11. The computing system of claim 9 wherein the output is specified in a JEDEC memory channel standard.

12. (canceled)

13. The computing system of claim 9 wherein the command decoding logic is to be coupled to CA signaling lines of a memory channel.

14. The computing system of claim 13 wherein the memory channel's specifications are defined in a JEDEC industry standard.

15. (canceled)

16. (canceled)

17. A memory chip, comprising:
an array of storage cells;
embedded memory circuitry to store information that identifies weak ones of the storage cells that deplete their charge more rapidly than other ones of the storage cells;
special refresh logic circuitry coupled to the embedded memory circuitry, the special refresh logic circuitry to cause weak ones of the storage cells to receive special refreshes in order to refresh the weak ones of the storage cells more frequently than the other ones of the storage cells, wherein, weaker cells on a same memory row as less weaker cells receive refreshes at a greater rate than the less weaker cells.

18. The memory chip of claim 17 wherein the special refresh logic circuitry is coupled to an internal memory of the memory chip that is to store information that identifies the weak ones of the storage cells.

19. The memory chip if claim 17 wherein the memory chip further comprises row hammer detection logic circuitry.

20. A memory controller, comprising:
refresh control logic circuitry comprising a first input to receive a baseline DRAM refresh rate and a second input to receive special refresh requests from a DRAM memory chip, the refresh control logic circuitry to control the providing of refresh signals to the DRAM memory chip according to the baseline refresh rate to refresh storage cells of the memory chip that will retain their data when refreshed at the baseline refresh rate, the refresh control logic circuitry to provide additional refresh signals to the DRAM memory chip in response to the special refresh requests in order to refresh other storage cells of the memory chip that will not retain their data when refreshed at the baseline refresh rate.
